(19) United States
(12) Patent Application Publication
(10) Pub. No.: US 2013/0265094 A1
(43) Pub. Date: Oct. 10, 2013

(54) LEVEL SHIFTER CIRCUIT

(71) Applicants: Samaksh Sinha, Singapore (SG); Sunny Gupta, Noida (IN)

(72) Inventors: Samaksh Sinha, Singapore (SG); Sunny Gupta, Noida (IN)

(73) Assignee: FREESCALE SEMICONDUCTOR, INC, Austin, TX (US)

(21) Appl. No.: 13/439,858

(22) Filed: Apr. 5, 2012

(51) Int. Cl. H03L 5/00

(52) U.S. Cl. 327/333

(57) ABSTRACT

A level shifter circuit for shifting voltage level of an input signal includes a supply voltage generation circuit, an inverter, and a cross-coupled latch. The supply voltage generation circuit generates a low-voltage supply using a high-voltage supply. The low-voltage supply is used by the inverter to generate an inverted input signal. The input signal and the inverted input signal are provided to the cross-coupled latch, which generates a level shifted output signal.

### BACKGROUND OF THE INVENTION

The present invention relates generally to digital voltage level shifter circuits, and, more particularly, to level shifter circuits that operate using a single voltage supply.

Modern day system-on-chip (SoC) circuits are designed to achieve low power consumption levels by lowering their operating voltage. To decrease the overall operating voltage, SoCs have multiple voltage domains operating at different voltage supply levels. Multiple voltage domains require stepping up/down of voltage levels of signals that cross voltage domains. Level shifter circuits are used to step up/down the signal voltage levels to synchronize the signal voltage level with the supply voltage level of the voltage domain in which the signal is being used.

Conventional level shifters operate using two voltage supplies to step up/down the voltage level of the input signal. The two voltage supplies include high and low voltage supplies that correspond to the voltage supply levels of the domains that the input signal traverses. The two voltage supplies require two separate routing tracks for each row of standard cells in the SoC design. Since the circuit density of SoCs is continually increasing, placement and routing of standard cells is becoming an increasingly difficult task. The requirement of additional routing tracks to route the two voltage supplies adds to placement and routing complexities and leads to congestion in functional nets.

Therefore, it would be advantageous to have a level shifter circuit that uses a single voltage supply and saves routing resources.

### BRIEF DESCRIPTION OF THE DRAWINGS

The following detailed description of the preferred embodiments of the present invention will be better understood when read in conjunction with the appended drawings. The present invention is illustrated by way of example, and not limited by the accompanying figures, in which like references indicate similar elements.

FIG. 1 is a schematic circuit diagram of a level shifter circuit in accordance with an embodiment of the present invention.

### DETAILED DESCRIPTION OF THE INVENTION

The detailed description of the appended drawings is intended as a description of the currently preferred embodiments of the present invention, and is not intended to represent the only form in which the present invention may be practiced. It is to be understood that the same or equivalent functions may be accomplished by different embodiments that are intended to be encompassed within the spirit and scope of the present invention.

In an embodiment of the present invention, a level shifter circuit is provided. The level shifter circuit generates an output signal based on an input signal and a first supply voltage and includes a supply voltage generation circuit for generating a second supply voltage that is less than the first supply voltage. The supply voltage generation circuit includes a plurality of diode-connected transistors, in which a source terminal of a first diode-connected transistor receives the first supply voltage and a drain terminal of the first diode-connected transistor is connected to a source terminal of a second diode-connected transistor. A first inverter circuit is connected to the supply voltage generation circuit. The first inverter circuit generates an inverted input signal based on the input signal and the second supply voltage. A cross-coupled latch circuit is connected to the first inverter circuit and generates the output signal and an inverted output signal based on the input and inverted input signals and the first supply voltage.

In another embodiment of the present invention, a level shifter circuit is provided. The level shifter circuit generates an output signal based on an input signal and a first supply voltage and includes a supply voltage generation circuit for generating a second supply voltage that is less than the first supply voltage. The supply voltage generation circuit includes a plurality of diode-connected transistors, in which a source terminal of a first diode-connected transistor receives the first supply voltage and a drain terminal of the first diode-connected transistor is connected to a source terminal of a second diode-connected transistor. Further, a first inverter circuit is connected to the supply voltage generation circuit. The first inverter circuit generates an inverted input signal based on the input signal and the second supply voltage. A cross-coupled latch circuit is connected to the first inverter circuit and generates the output signal and an inverted output signal based on the input and inverted input signals and the first supply voltage. The cross-couple latch circuit includes a third transistor having a source terminal that receives the first supply voltage for generating the inverted output signal. The cross-coupled latch circuit further includes a fourth transistor having a source terminal that receives the first supply voltage, a gate terminal connected to a drain terminal of the third transistor, a drain terminal connected to a gate terminal of the third transistor. The fourth transistor generates the output signal. Further, the cross-coupled latch circuit includes a fifth transistor having a drain terminal connected to the drain terminal of the third transistor, a gate terminal that receives the input signal, and a source terminal that receives the third supply voltage. Still further, the cross-coupled latch circuit includes a sixth transistor having a drain terminal connected to the drain terminal of the fourth transistor, a gate terminal connected to the drain terminals of the first and second transistors, and a source terminal that receives the third supply voltage.

In yet another embodiment of the present invention, a level shifter circuit is provided. The level shifter circuit generates an output signal based on an input signal and a first supply voltage and includes a supply voltage generation circuit for generating a second supply voltage that is less than the first supply voltage. The supply voltage generation circuit includes a plurality of diode-connected transistors, in which a source terminal of a first diode-connected transistor receives the first supply voltage and a drain terminal of the first diode-connected transistor is connected to a source terminal of a second diode-connected transistor. Further, a first inverter circuit is connected to the supply voltage generation circuit. The first inverter circuit generates an inverted input signal based on the input signal and the second supply voltage. A cross-coupled latch circuit is connected to the first inverter circuit and generates first and second intermediate signals based on the input and inverted input signals and the first supply voltage. The cross-coupled latch circuit includes a third transistor having a source terminal that receives the first supply voltage for generating the first intermediate signal. The cross-coupled latch circuit further includes a fourth transistor having a source terminal that receives the first supply voltage, a gate terminal connected to a drain terminal of the third transistor, a drain terminal connected to a gate terminal of the third transistor. The fourth transistor generates the second intermediate signal. Further, the cross-coupled latch circuit includes a fifth transistor having a drain terminal connected to the drain terminal of the third transistor, a gate terminal that receives the input signal, and a source terminal that receives the third supply voltage. Still further, the cross-coupled latch circuit includes a sixth transistor having a drain terminal connected to the drain terminal of the fourth transistor, a gate terminal connected to the drain terminals of the first and second transistors, and a source terminal that receives the third supply voltage. The level shifter circuit further includes an output buffer circuit connected to the cross-coupled latch circuit. The output buffer circuit generates the output signal and an inverted output signal based on the first and second intermediate signals and the first supply voltage.

Various embodiments of the present invention provide a level shifter circuit that includes a supply voltage generation circuit for generating a low-voltage supply by using a high-voltage supply. The supply voltage generation circuit includes a plurality of diode-connected transistors. Metal options are provided at each node to connect and select one or more diode-connected transistors and provide a drop in the high-voltage supply to generate the low-voltage supply. The low-voltage supply is provided to an inverter circuit that inverts an input signal to generate an inverted input signal. The input and inverted input signals are provided to a cross-coupled latch circuit to generate an output signal that is level shifted from the input signal. Thus, the inverted input signal which is necessary for the cross-coupled latch circuit is generated internally by using the low-voltage supply generated by the supply generation circuit and eliminates the need for an external low-voltage supply in addition to the high-voltage supply. The SoC routing resources are saved as no extra power routing track is required for each row of standard cells in the SoC. The free routing resources may be used for routing functional nets, relieve congestion, and eliminate the need for a larger die area. Thus, the overall cost of the SoC is reduced. Further, the level shifter has a minimal impact on the die area. Additionally, the metal options provide the flexibility of selecting a desired number of diode-connected transistors to generate low-voltage supply with a desired magnitude, when high-voltage supplies with higher magnitudes are used.

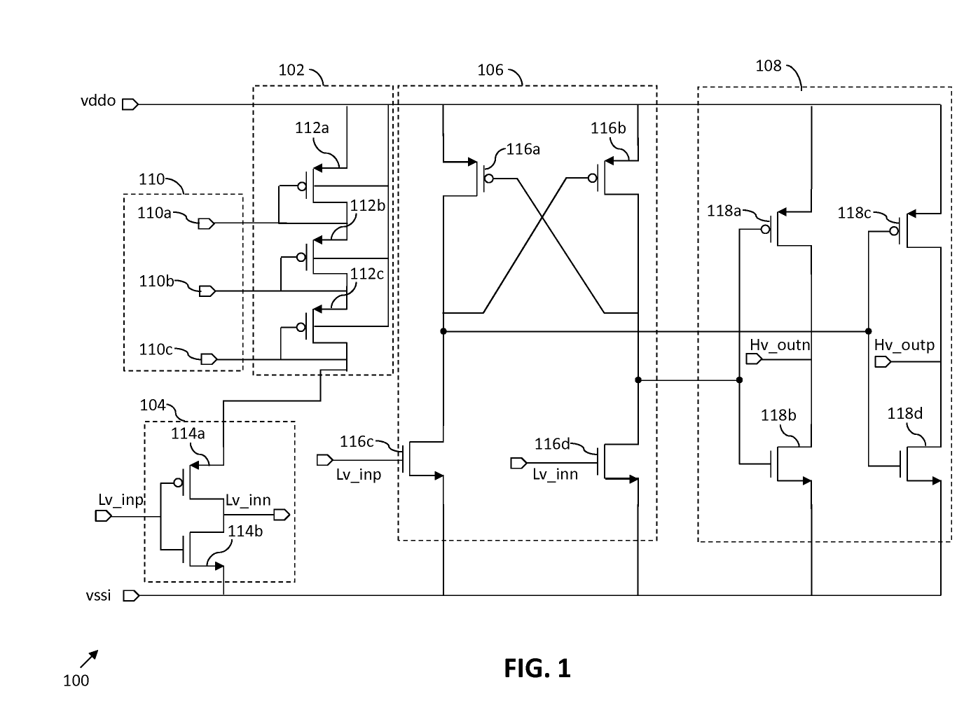

Referring now to FIG. 1, a schematic circuit diagram of a level shifter circuit 100 in accordance with an embodiment of the present invention is shown. The level shifter circuit 100 includes a supply voltage generation circuit 102, a first inverter circuit 104, a cross-coupled latch circuit 106, an output buffer circuit 108, and a plurality of metal options 110, which in the embodiment shown is first through third metal options 110a-110c. The supply voltage generation circuit 102 includes a plurality of diode-connected transistors. The embodiment shown has first through third diode-connected transistors 112a-112c. The first inverter circuit 104 includes first and second transistors 114a and 114b. The cross-coupled latch circuit 106 includes third through sixth transistors 116a-116d. The output buffer circuit 108 includes seventh through tenth transistors 118a-118d.

A high-voltage supply, V_{ddo}, is connected to a source terminal of the first diode-connected transistor 112a and a drain terminal of the first diode-connected transistor 112a is connected to a source terminal of the second diode-connected transistor 112b. A drain terminal of the second diode-connected transistor 112b is connected to a source terminal of the third diode-connected transistor 112c and a drain terminal the third diode-connected transistor 112c is connected to a source terminal of the first transistor 114a of the first inverter 104. First, second, and third metal options 110a, 110b, and 110c are provided at nodes that connect the first and second diode-connected transistors 112a and 112b, the second and third diode-connected transistors 112b and 112c, and the third diode-connected transistor 112c and the first transistor 114a, respectively, as shown. More particularly, each metal option 110a-110c is connected to the gate and drain terminals of one of the diode connected transistors 112a-112c. Additionally, body terminals of the first, second, and third diode-connected transistors 112a, 112b, and 112c are connected to the high-voltage supply V_{ddo}.

A drain terminal of the first transistor 114a is connected to a drain terminal of the second transistor 114b. A source terminal of the second transistor 114b is connected to a second supply voltage line, Vₛₛᵢ (for example, a ground voltage). Gate terminals of the first and second transistors 114a and 114b receive an input signal (Lv_inp) from a logic domain.

Regarding the cross-coupled latch circuit 106, gate terminals of the third and fourth transistors 116a and 116b are connected to drain terminals of the fourth and third transistors 116b and 116a, respectively, in a cross-coupled configuration. Source terminals of the third and fourth transistors 116a and 116b are connected to the high-voltage supply V_{ddo}. The drain terminals of the third and fourth transistors 116a and 116b are further connected to drain terminals of the fifth and sixth transistors 116c and 116d, respectively. A gate terminal of the fifth transistor 116c is connected to the gate terminals of the first and second transistors 114a and 114b and a gate terminal of the sixth transistor 116d is connected to the drain terminals of the first and second transistors 114a and 114b. The source terminals of the fifth and sixth transistors 116c, 116d are connected to the second supply voltage line Vₛₛᵢ.

Regarding the output buffer circuit 108, source terminals of the seventh and ninth transistors 118a, 118c are connected to the high-voltage supply, V_{ddo}, and drain terminals of the seventh and ninth transistors 118a, 118c are connected to drain terminals of the eighth and tenth transistors 118b, 118d, respectively. Gate terminals of the seventh and eighth transistors 118a and 118b are connected to the drain terminals of the fourth and sixth transistors 116b, 116d, and gate terminals of the ninth and tenth transistors 118c, 118d are connected to the drain terminals of the third and fifth transistors 116a, 116c, respectively. The source terminals of the eighth and tenth transistors 118b, 118d are connected to the second supply voltage Vₛₛᵢ.

A low-voltage supply is generated by the supply voltage generation circuit 102 using the high-voltage supply V_{ddo}. The metal options 110 are used to select one or more of the diode-connected transistors 112 to generate the low-voltage supply at a desired magnitude. A lower range of the low-voltage supply is chosen based on threshold voltages of the first and second transistors 114a and 114b and an upper range is chosen based on an upper range of the input signal. The selected diode-connected transistors 112 provide a drop in the high-voltage supply V_{ddo} to generate the low-voltage supply at the desired magnitude. For example, when the high-voltage supply V_{ddo} has a magnitude of 2.5 volts (V) and the range of the low-voltage supply is 0.9-1.2 V, a drop of 1.6V (2.5V-0.9V) is provided using the diode-connected transistors 112. In this case, the first and second transistors 112a, 112b are selected by shorting the first and second metal options 110a and 110b to provide a drop of ˜1.4V (2 * threshold voltage of 0.7V). Further, when the high-voltage supply V_{ddo} provides a voltage greater than 2.5V, three diode-connected transistors are selected to provide the desired voltage drop. Such metal options are used during the design stage of the circuit whereby small edits or changes to the design file that specify or select certain ones of the metal options are made so that the desired voltage levels are achieved.

In an embodiment of the present invention, the supply voltage generation circuit 102 includes more than three diode-connected transistors 112 so that it can generate a low-voltage supply using the high-voltage supply that has a magnitude higher than 2.5V. Thus, different numbers of diode-connected transistors 112 may be selected using the metal options 110 to generate a low-voltage supply of a desired magnitude even when the magnitude of the high-voltage supply is changed. In an embodiment of the present invention, the diode-connected transistors 112 are n-channel metal-oxide-semiconductor (NMOS) transistors.

The low-voltage supply is provided to the source terminal of the first transistor 114a by way of the drain terminal of the third diode-connected transistor 112c. The voltage supply Vₛₛᵢ is provided to the source terminal of the second transistor 114b. In an embodiment of the present invention, the first and second transistors 114a and 114b are p-channel metal-oxide-semiconductor (PMOS) and NMOS transistors, respectively. The input signal is provided to the gate terminals of the first and second transistors 114a and 114b, which invert the input signal and generate an inverted input signal Lv_inn by way of the drain terminals thereof.

The input and inverted input signals are provided to the gate terminals of the fifth and sixth transistors 116c and 116d, respectively. As mentioned above, the fifth and sixth transistors 116c and 116d are part of the cross-coupled latch circuit 106. In an embodiment of the present invention, the fifth and sixth transistors 116c and 116d are NMOS transistors and the third and fourth transistors 116a and 116b are PMOS transistors. The cross-coupled configuration facilitates settling the voltage levels at the drain terminals of the fifth and sixth transistors 116c and 116d. For example, when the input signal is at logic zero, the inverted input signal is at logic one, which causes the fifth transistor 116c to switch off and the sixth transistor 116d to switch on. As the sixth transistor 116d is switched on, voltage at its drain terminal is pulled down, which pulls down the voltage at the gate terminal of the third transistor 116a and switches the third transistor 116a on. The switching on of the third transistor 116a pulls up the voltage at its drain terminal to the high voltage supply level V_{ddo}. Since the drain terminal of the third transistor 116a is connected to the gate terminal of the fourth transistor 116b, the gate voltage is pulled high, which pushes the fourth transistor 116b into deep cut-off region, and thus switches it off. Additionally, the pulling up of the voltage at the drain terminal of the third transistor 116a causes the voltage at the drain terminal of the fifth transistor 116c to be pulled up, which pushes the fifth transistor 116c into the deep cut-off region. Thus, the cross-coupled configuration operates as a positive feedback loop and reinforces the on and off switching of the fifth and sixth transistors 116c and 116d, respectively.

An inverted output signal is generated at the drain terminals of the third and fifth transistors 116a and 116c and an output signal is generated by the drain terminals of the fourth and sixth transistors 116b and 116d. The voltage levels of the output and inverted output signals are shifted up from a voltage level of the input signal to the high-voltage supply level V_{ddo}.

In an embodiment of the present invention, the level shifter circuit 100 optionally includes the output buffer circuit 108 connected to the cross-coupled latch circuit 106. The output buffer circuit 108 provides drive-strength to the output and inverted output signals. The output buffer circuit 108 inverts the output signal provided to the gate terminals of the seventh and eighth transistors 118a and 118b to generate the inverted output signal and inverts the inverted output signal provided to the gate terminals of the ninth and tenth transistors 118c and 118d to generate the output signal.

While various embodiments of the present invention have been illustrated and described, it will be clear that the present invention is not limited to these embodiments only. Numerous modifications, changes, variations, substitutions, and equivalents will be apparent to those skilled in the art, without departing from the spirit and scope of the present invention, as described in the claims.

1. A level shifter circuit for generating an output signal based on an input signal and a first supply voltage, the level shifter circuit comprising:
a supply voltage generation circuit for generating a second supply voltage that is less than the first supply voltage, wherein the supply voltage generation circuit includes a plurality of diode-connected transistors, wherein a source terminal of a first diode-connected transistor receives the first supply voltage and a drain terminal of the first diode-connected transistor is connected to a source terminal of a second diode-connected transistor, and a gate terminal of the first diode-connected transistor is connected to the drain terminal of the first diode-connected transistor, and a gate terminal of the second diode-connected transistor is connected to a drain terminal of the second diode-connected transistor, and body terminals of the first and second diode-connected transistors are connected to the first supply voltage;
a first inverter circuit, connected to the supply voltage generation circuit, for generating an inverted input signal based on the input signal and the second supply voltage;
a cross-coupled latch circuit, connected to the first inverter circuit, for generating the output signal and an inverted output signal based on the input and inverted input signals and the first supply voltage; and
a plurality of metal options respectively connected to the gates and drains of respective ones of the plurality of diode-connected transistors, wherein a voltage level of the second supply voltage is selected using the metal options.

2. The level shifter circuit of claim 1, wherein the first inverter circuit comprises:
a first transistor having a source terminal connected to the supply voltage generation circuit, and a gate terminal that receives the input signal; and
a second transistor having a drain terminal connected to a drain terminal of the first transistor, a source terminal that receives a third supply voltage, and a gate terminal connected to the gate terminal of the first transistor.

3. The level shifter circuit of claim 2, wherein the cross-coupled latch circuit comprises:
a third transistor having a source terminal that receives the first supply voltage for generating the inverted output signal;
a fourth transistor having a source terminal that receives the first supply voltage, a gate terminal connected to a drain terminal of the third transistor, and a drain terminal connected to a gate terminal of the third transistor, wherein the fourth transistor generates the output signal;
a fifth transistor having a drain terminal connected to the drain terminal of the third transistor, a gate terminal that receives the input signal, and a source terminal that receives the third supply voltage; and
a sixth transistor having a drain terminal connected to the drain terminal of the fourth transistor, a gate terminal connected to the drain terminals of the first and second transistors, and a source terminal that receives the third supply voltage.

4. The level shifter circuit of claim 3, further comprising an output buffer circuit connected to the cross-coupled latch circuit, for providing drive strength to the output and the inverted output signals.

5. The level shifter circuit of claim 4, wherein the output buffer circuit comprises:
a second inverter circuit, including:
a seventh transistor having a source terminal that receives the first supply voltage, and a gate terminal connected to the drain terminals of the fourth and sixth transistors for receiving the output signal; and
an eighth transistor having a source terminal that receives the third supply voltage, a gate terminal connected to the drain terminals of the fourth and sixth transistors for receiving the output signal, and a drain terminal connected to a drain terminal of the seventh transistor; and
a third inverter circuit, including:
a ninth transistor having a source terminal that receives the first supply voltage and a gate terminal connected to the drain terminals of the third and fifth transistors for receiving the inverted output signal; and
a tenth transistor having a source terminal that receives the third supply voltage, a gate terminal connected to the drain terminals of the third and fifth transistors for receiving the inverted output signal, and a drain terminal connected to a drain terminal of the ninth transistor.

6. The level shifter circuit of claim 5, wherein the plurality of diode-connected transistors and the first, third, fourth, seventh, and ninth transistors are p-channel metal-oxide semiconductor (PMOS) transistors.

7. The level shifter circuit of claim 6, wherein the second, fifth, sixth, eighth, and tenth transistors are n-channel metal-oxide semiconductor (NMOS) transistors.

8. The level shifter circuit of claim 7, wherein the third supply voltage is a ground level voltage.

9. (canceled)

10. (canceled)

11. A level shifter circuit for generating an output signal based on an input signal and a first supply voltage, the level shifter circuit comprising:
a supply voltage generation circuit for generating a second supply voltage that is less than the first supply voltage, wherein the supply voltage generation circuit includes a plurality of diode-connected transistors, wherein a source terminal of a first diode-connected transistor receives the first supply voltage and a drain terminal of the first diode-connected transistor is connected to a source terminal of a second diode-connected transistor, a gate terminal of the first diode-connected transistor is connected to the drain terminal of the first diode-connected transistor, and a gate terminal of the second diode-connected transistor is connected to a drain terminal of the second diode-connected transistor, and body terminals of the first and second diode-connected transistors are connected to the first supply voltage, and wherein the plurality of diode-connected transistors generate the second supply voltage based on one or more metal options, wherein the metal options are respectively connected to the gates and drains of respective ones of the plurality of diode-connected transistors and a voltage level of the second supply voltage is selected using the metal options;
a first inverter circuit having first and second transistors that receive the input signal, wherein the first inverter circuit is connected to the supply voltage generation circuit for generating an inverted input signal based on the input signal and the second supply voltage; and
a cross-coupled latch circuit, connected to the first inverter circuit, for generating the output signal and an inverted output signal based on the input and inverted input signals and the first supply voltage, including:
a third transistor having a source terminal that receives the first supply voltage for generating the inverted output signal;
a fourth transistor having a source terminal that receives the first supply voltage, a gate terminal connected to a drain terminal of the third transistor, a drain terminal connected to a gate terminal of the third transistor, wherein the fourth transistor generates the output signal;
a fifth transistor having a drain terminal connected to the drain terminal of the third transistor, a gate terminal that receives the input signal, and a source terminal that receives the third supply voltage; and
a sixth transistor having a drain terminal connected to the drain terminal of the fourth transistor, a gate terminal connected to the drain terminals of the first and second transistors, and a source terminal that receives the third supply voltage.

12. The level shifter circuit of claim 11, further comprising an output buffer circuit, connected to the cross-coupled latch circuit, for providing drive strength to the output and inverted output signals.

13. The level shifter circuit of claim 12, wherein the output buffer circuit comprises:
a second inverter circuit, including:
a seventh transistor having a source terminal that receives the first supply voltage, and a gate terminal connected to the drain terminals of the fourth and sixth transistors for receiving the output signal; and
an eighth transistor having a source terminal that receives the third supply voltage, a gate terminal connected to the drain terminals of the fourth and sixth transistors for receiving the output signal, and a drain terminal connected to a drain terminal of the seventh transistor; and
a third inverter circuit, including:
a ninth transistor having a source terminal that receives the first supply voltage and a gate terminal connected to the drain terminals of the third and fifth transistors for receiving the inverted output signal; and
a tenth transistor having a source terminal that receives the third supply voltage, a gate terminal connected to the drain terminals of the third and fifth transistors for receiving the inverted output signal, and a drain terminal connected to a drain terminal of the ninth transistor.

14. The level shifter circuit of claim 13, wherein the plurality of diode-connected transistors and the first, third, fourth, seventh, and ninth transistors are p-channel metal-oxide semiconductor (PMOS) transistors.

15. The level shifter circuit of claim 14, wherein the second, fifth, sixth, eighth, and tenth transistors are n-channel metal-oxide semiconductor (NMOS) transistors.

16. (canceled)

17. A level shifter circuit for generating an output signal based on an input signal and a first supply voltage, the level shifter circuit comprising:
a supply voltage generation circuit for generating a second supply voltage that is less than the first supply voltage, wherein the supply voltage generation circuit includes a plurality of diode-connected transistors, wherein a source terminal of a first diode-connected transistor receives the first supply voltage and a drain terminal of the first diode-connected transistor is connected to a source terminal of a second diode-connected transistor, a gate terminal of the first diode-connected transistor is connected to the drain terminal of the first diode-connected transistor, and a gate terminal of the second diode-connected transistor is connected to a drain terminal of the second diode-connected transistor, and body terminals of the first and second diode-connected transistors are connected to the first supply voltage, wherein the plurality of diode-connected transistors generate the second supply voltage based on one or more metal options, wherein the metal options are respectively connected to the gates and drains of respective ones of the plurality of diode-connected transistors and a voltage level of the second supply voltage is selected using the metal options;
a first inverter circuit having first and second series connected transistors that receive the input signal at their gate terminals and generate an inverted input signal at their drain terminals, wherein the first inverter circuit is connected between the supply voltage generation circuit and a third supply voltage;
a cross-coupled latch circuit, connected to the first inverter circuit, for generating first and second intermediate signals based on the input and inverted input signals and the first supply voltage, including:
a third transistor having a source terminal that receives the first supply voltage for generating the first intermediate signal;
a fourth transistor having a source terminal that receives the first supply voltage, a gate terminal connected to a drain terminal of the third transistor, a drain terminal connected to a gate terminal of the third transistor, wherein the fourth transistor generates the second intermediate signal;
a fifth transistor having a drain terminal connected to the drain terminal of the third transistor, a gate terminal that receives the input signal, and a source terminal that receives the third supply voltage; and
a sixth transistor having a drain terminal connected to the drain terminal of the fourth transistor, a gate terminal connected to the drain terminals of the first and second transistors, and a source terminal that receives the third supply voltage; and
an output buffer circuit, connected to the cross-coupled latch circuit, for generating the output signal and an inverted output signal based on the first and second intermediate signals and the first supply voltage.

18. The level shifter circuit of claim 17, wherein the output buffer circuit comprises:
a second inverter circuit for generating an inverted output signal, wherein the second inverter circuit includes:
a seventh transistor having a source terminal that receives the first supply voltage, and a gate terminal connected to the drain terminals of the fourth and sixth transistors for receiving the second intermediate signal; and
an eighth transistor having a source terminal that receives the third supply voltage, a gate terminal connected to the drain terminals of the fourth and sixth transistors, and a drain terminal connected to a drain terminal of the seventh transistor for receiving the second intermediate signal; and
a third inverter circuit for generating the output signal, wherein the third inverter circuit includes:
a ninth transistor having a source terminal that receives the first supply voltage, and a gate terminal connected to the drain terminals of the third and fifth transistors for receiving the first intermediate signal; and
a tenth transistor having a source terminal that receives the third supply voltage, a gate terminal connected to the drain terminals of the third and fifth transistors for receiving the first intermediate signal, and a drain terminal connected to a drain terminal of the ninth transistor.

19. (canceled)

20. The level shifter circuit of claim 18, wherein the third supply voltage is a ground level voltage.
